(19) United States
(12) Patent Application Publication
(10) Pub. No.: US 2023/0067677 A1
(43) Pub. Date: Mar. 2, 2023

(54) SEQUENCES AND EQUIPMENT FOR DIRECT BONDING

(71) Applicant: INVENSAS BONDING TECHNOLOGIES, INC., San Jose, CA (US)

(72) Inventors: Bongsub Lee, Mountain View, CA (US); Rajesh Katkar, Milpitas, CA (US)

(21) Appl. No.: 17/816,332

(22) Filed: Jul. 29, 2022

Related U.S. Application Data
(60) Provisional application No. 63/239,681, filed on Sep. 1, 2021.

(51) Int. Cl. B23K 26/21; B23K 26/352

(52) U.S. Cl. CPC B23K 26/21; B23K 26/352

(57) ABSTRACT

Bonding tools and related systems are provided for surface cleaning and direct bonding. A bonding tool includes a support configured to hold a first element, and is further configured to bond a second element to the first element by way of direct bonding. A laser cleaning assembly is configured to clean the first and/or second element prior to bonding, and can be integrated with the bonding tool. The laser cleaning can also clean surfaces of the bonding tool and/or a robotic end effector for delivering the second element. Methods and sequences for surface cleaning and direct bonding using the systems are also disclosed.

### CROSS-REFERENCE TO RELATED APPLICATIONS

This application claims priority to U.S. Provisional Application No. 63/239,681, filed Sep. 1, 2021, titled “SEQUENCES AND EQUIPMENT FOR DIRECT BONDING”, the disclosure of which is incorporated herein by reference in its entirety for all purposes.

### BACKGROUND

### Field

The field generally relates to systems and methods for surface cleaning and direct bonding, and more particularly, to systems and methods having laser cleaning capabilities.

### Description of the Related Art

Contaminants such as micron and submicron sized particles on semiconductor surfaces can pose serious problems such as circuit failure and yield loss in a semiconductor device. Contamination control on silicon wafers is therefore a crucial issue in manufacturing processes. Certain cleaning techniques such as high-pressure gas jet, scrubbing, ultrasonic and chemical flux, may be effective, but can entail post-cleaning rinse steps and time for surface drying prior to further processing.

Direct bonding, including hybrid direct bonding, is very sensitive to any particulate contamination on the surfaces of interest. Slight contamination can interfere with full bonding across the elements and adversely affect yield. Even after effective cleaning, delays between cleaning and bonding, and robotic handling prior to bonding, can lead to levels of contamination that affect yield.

There remains a continuing need for more effective techniques to remove particles from the semiconductor surface.

### BRIEF DESCRIPTION OF THE DRAWINGS

Specific implementations will now be described with reference to the following drawings, which are provided by way of example, and not limitation.

FIG. 1 schematically illustrates a cleaning process using laser-induced shock wave according to some embodiments of the disclosed technology.

FIG. 2 schematically illustrates an example cleaning and bonding sequence.

FIG. 3 schematically illustrates another example cleaning and bonding sequence.

FIG. 4 schematically shows a top-down view of an example system which can perform the cleaning and bonding sequence illustrated in FIG. 3.

FIG. 5 schematically illustrates yet another example cleaning and bonding sequence.

FIG. 6 schematically illustrates an example of a cleaning and bonding system which can clean two elements.

FIG. 7 schematically illustrates an example use of the disclosed systems and methods to clean a flip tool.

### DETAILED DESCRIPTION

In some embodiments, the present disclosure provides a way of effectively cleaning semiconductor surfaces prior to direct bonding of a first element to a second element. Laser cleaning is provided to provide a quick final process that can be used directly prior to bonding processes, with reduced time, storage and re-contamination issues raised by traditional stand-alone cleaning apparatus. By integrating the laser cleaning with a bonding tool, more effective cleaning can be provided with reduced risk of re-contamination prior to bonding.

In some embodiments, a laser-cleaning assembly can be integrated with the bonding tool, for example as a module attached at a side of the bonding tool or integrated with a die-handling arm of the bonding tool itself. Safety walls can be provided to protect against damage from escaping radiation at the laser wavelength. For example, the walls may be opaque, or may filter/block the laser wavelengths while transparent to other wavelengths. The walls may also aid in containing and directing collection of dislodged particles.

In some embodiments, the laser can be directed normal to the die or wafer surface to be cleaned. Optics can be provided to diffuse the laser to an area covering an entire die. Alternatively, or additionally, the laser-cleaning assembly can be moved relative to the die or wafer surface to clean the entire bonding surface of interest by scanning. Particles and organic residue may be cleaned.

In some embodiments, the laser can have a lateral component, such as a parallel to the bonding surface of interest, and thereby induce a shock wave to dislodge particles from a bonding surface. In such embodiments, the laser beam can be focused on a focal point in the fluid (e.g., air or supplied gases) near the surface by a lens so that the fluid around the focal point may be ionized to generate a laser induced plasma and shock wave which cleans the bonding surface. In some embodiments, each generated shock wave can clean a relatively small or focused area of the bonding surface, e.g., of about a square inch. For larger dies or wafers, the focus of the laser can be moved to scan across the bonding surface of interest.

In some embodiments, the laser induced plasma shock wave may be used to effectively remove particulate contamination. In some embodiments, the present disclosure provides cleaning processes that are effective for nanoscale or microscale particles (for example, particles of about 10 μm to 2 nm, or between about 1 μm and 4 nm), and even particles welded to the surface. In some embodiments, the present disclosure provides cleaning processes that may not require the use of certain tools and chemical agents which may introduce new contaminates or entail additional time or storage between cleaning and bonding.

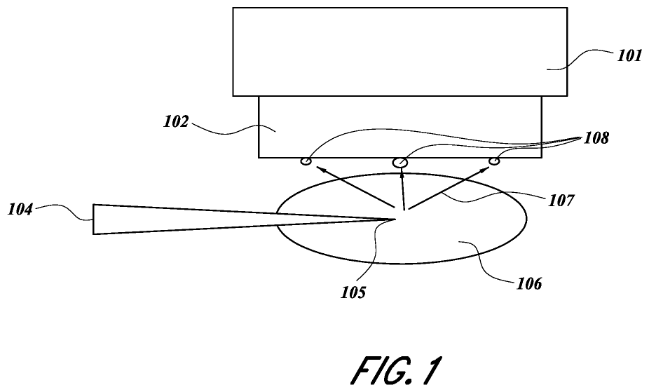

FIG. 1 illustrates a cleaning process using laser-induced shock wave, or “laser shock cleaning”. Laser shock cleaning can focus a laser beam in a fluid (e.g., ambient air or supplied liquid or gas) near a solid surface and utilize laser-induced fluid jet or shock wave to clean the solid surface; the laser beam does not directly irradiate onto the solid surface. See U.S. Pat. No. 6,777,642, the disclosure of which is incorporated herein by reference in its entirety for all purposes, for further details regarding laser shock cleaning. A second element, such as the illustrated die 102 is picked up and held in place by robotic pick-and-place tool 101, such as a flip tool, and a laser beam 104 is focused on a focal point 105 (“laser focus”) near the die 102 to generate a laser induced plasma 106 and shock wave 107, which can dislodge particles 108 from the surface of the die 102. The laser beam 104 may be directed laterally, for example parallel to the die 102 surface. The die 102 can be a semiconductor die, such as an integrated circuit or an electronic component. The skilled artisan will appreciate that exact parallel alignment is not necessary to accomplish the desired cleaning, as long as the focal point 105 is within the desired distance from the die 102 bonding surface to achieve effective cleaning, such that the laser beam 104 may have a significant or predominant lateral component. In some embodiments, the vertical distance between the focal point 105 and the die 102 surface may be between about 0.1 mm and 5 cm, more particularly between about 0.5 mm and 10 mm, or any value therebetween. In some embodiments, the vertical distance between the focal point 105 and the die 102 surface may be about 0.8 mm to 2 mm. In some embodiments, the output wavelength of the laser is between about 100 nm to about 1500 nm, or more particularly between about 400 nm to about 1200 nm. An example laser for such purposes is a neodymium-doped yttrium aluminum garnet (Nd:YAG) laser with an output wavelength of about 1064 nm. In some embodiments, the laser may output with a pulse frequency of about 0.5 to about 50 pulses per second, more particularly about 1 to about 20 pulses per second. In some embodiments, the laser may output with a pulse period of about 0.01 nanosecond to about 100 nanoseconds, more particularly about 20 nanoseconds to about 50 nanoseconds. In some embodiments, the laser may output with a pulse energy of about 10 mJ to about 100 J, more particularly about 100 mJ to about 1 J.

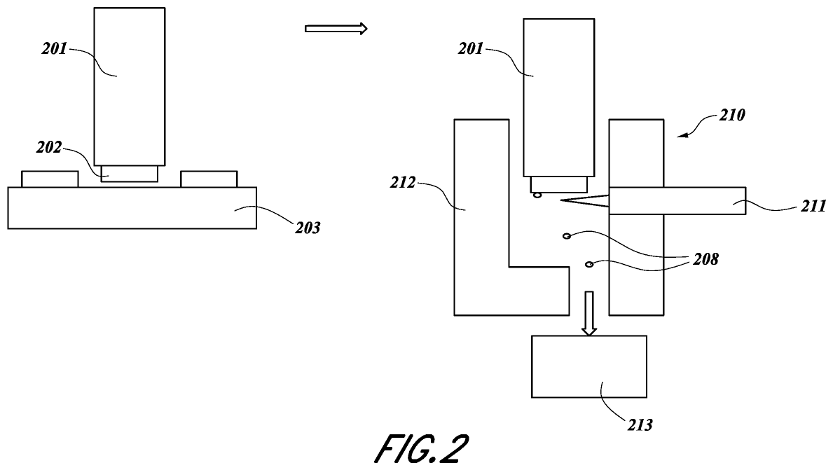

FIG. 2 illustrates an example cleaning and bonding sequence. An element, such as the illustrated die 202, is picked up by a robotic pick-and-place tool 201, for example from a film frame 203 from a singulation tool where a wafer has been singulated into individual dies, and then moved to a laser cleaning assembly area. The die 202 can be an electronic element (e.g., MEMS device, passive component), a semiconductor element (e.g., an integrated circuit die) or an optical element (e.g., a lens, filter, grating, emitter or sensor device). The laser cleaning assembly area may be attached to the bonder equipment (e.g., a direct bonding tool). In the illustrated embodiment, the bonding tool is configured for room temperature, atmospheric pressure direct bonding, such as the ZIBOND® and DBI® (hybrid direct bonding) processes commercially available from Xperi, Inc. of San Jose, Calif. In other embodiments, the bonding tool is configured for low-temperature die-to-wafer or die-to-die hybrid bonding technologies, such as the DBI® Ultra process commercially available from Xperi, Inc. of San Jose, Calif. The bonding tool includes a support to hold a host die or wafer (or substrate or carrier) in place when the die is placed thereon for direct bonding. The skilled artisan will appreciate that the embodiments taught herein can also be applied to other bonding tools that may entail application of pressure and/or temperature during the bonding. The laser cleaning assembly 210 may include a laser 211 and a chamber 212 attached to the bonding tool. The cleaning process, for example the one illustrated in FIG. 1, may then take place in the chamber 212. In some embodiments, the cleaning process may involve steam laser cleaning. The laser cleaning assembly 210 may further include a vacuum evacuator 213 which applies a negative pressure to the chamber, or at least to the region below the surface being cleaned, to remove the particles 208 detached from the surface of the die 202 and prevent such particles 208 from reattaching to the die 202 or contaminating the equipment. Then, the cleaned die 202 may be moved to a bonding location for bonding (for example, direct bonding, such as the ZIBOND® and DBI® and DBI® Ultra processes) to a wafer or to another die.

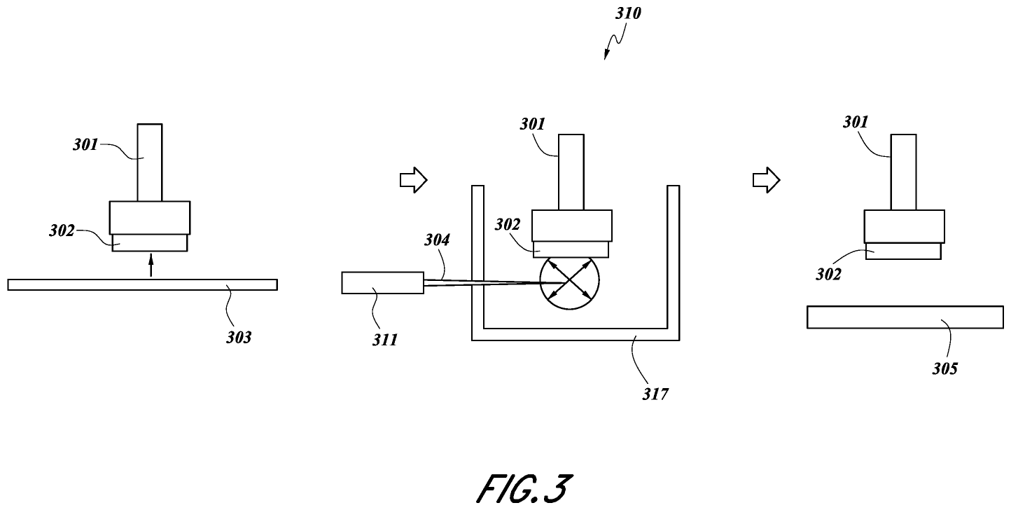

FIG. 3 illustrates another example cleaning and bonding sequence. An element, such as the illustrated die 302, is picked up from a tape or a die carrier 303 by a robotic end effector 301, such as that of a flip tool. The robotic end effector 301 may be integrated with the bonding tool, and the tape or carrier 303 may be mounted at or near the bonding tool for access by the robot. Then, the die 302 is moved to a laser cleaning assembly 310 for laser cleaning. In some embodiments, each laser cleaning event may last for about 0.01 second to about 10 seconds, or more particularly for about 0.1 second to 2 seconds. The laser cleaning may be performed by the process illustrated in FIG. 1. In some embodiments, the cleaning process may involve steam laser cleaning. The laser cleaning assembly 310 may include a laser 311 for emitting a laser beam 304 and a chamber. Walls 317 of the chamber may be opaque or may include optical filters to block the laser wavelength for safety measures. Then, the cleaned die 302 may be moved to a location for bonding (for example, direct bonding, such as the ZIBOND® and DBI® and DBI® Ultra processes) with another element 305 (a wafer or a die) being held by a support of the bonding tool.

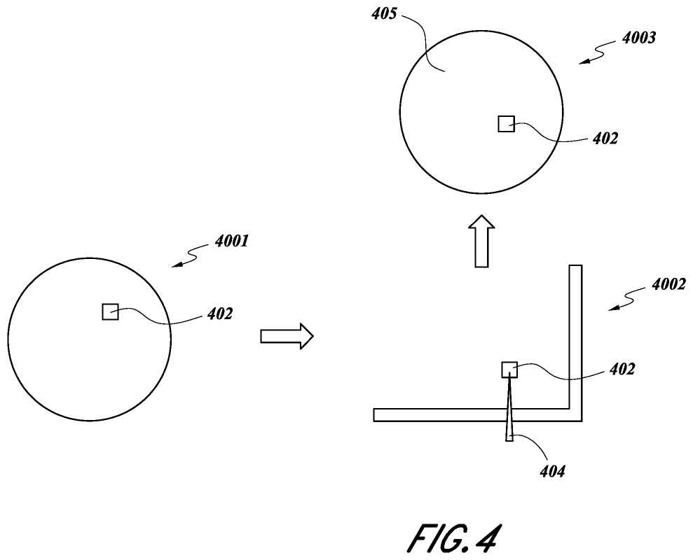

FIG. 4 shows a top-down view of an example system which can perform the cleaning and bonding sequence illustrated in FIG. 3. The system includes an area 4001 for picking up, and possibly flipping, a die 402, an area 4002 for laser cleaning by a laser beam 404, such as one configured for the cleaning process illustrated in FIG. 1, and an area 4003 for bonding (for example, direct bonding, such as the ZIBOND® and DBI® and DBI® Ultra processes) to a second element. In some embodiments, the cleaning process may involve steam laser cleaning. The die 402 can be picked from a film frame or tape after dicing. The second element can be, for example, a wafer 405 as illustrated. As previously noted, the laser cleaning area 4002, including its containing walls, any vacuum application equipment and handling robotics, can be integrated with the bonding region and be part of the bonding tool.

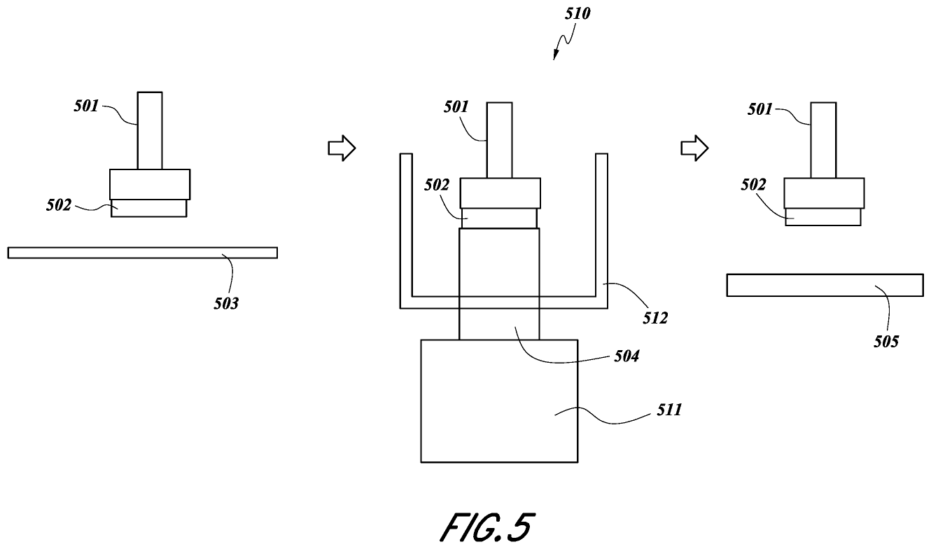

FIG. 5 illustrates yet another example cleaning and bonding sequence. An element, such as the illustrated die 502, is picked up from a tape, film frame or other die carrier 503 by a robotic end effector 501, such as that of a flip tool. Then, the die 502 is moved to a laser cleaning assembly 510, which may be attached to and form part of the bonding tool, for laser cleaning. In some embodiments, each laser cleaning event may last for about 0.01 second to about 10 seconds, or more particularly for about 0.1 second to 2 seconds. The laser cleaning assembly 510 may include a light source (e.g., a laser) and a chamber 512. The laser cleaning process may involve using direct irradiation of a laser beam 504 (e.g., from a laser source 511) onto the die 502 surface to remove the particles on the die 502 surface, for example, by way of dry laser cleaning or steam laser cleaning. In either dry or steam laser cleaning, the laser beam 504 may be directed, for example, normal or orthogonally, to directly impinge upon the die 502 surface. In some embodiments, in steam laser cleaning, the laser beam can alternatively be directed laterally or parallel to the die surface. In some embodiments, the output wavelength of the laser is between about 100 nm to about 1500 nm, or more particularly between about 400 nm to about 1200 nm. Example lasers for such purposes may include diode lasers emitting light in the blue or green color range, such as InGaN-based laser diodes emitting at wavelengths in the ranges of 445-465 nm or 510-525 nm. In some embodiments, the laser may output with a pulse frequency of about 0.5 to about 50 pulses per second, more particularly about 1 to about 20 pulses per second. In some embodiments, the laser may output with a pulse period of about 0.01 nanosecond to about 100 nanoseconds, more particularly about 20 nanoseconds to about 50 nanoseconds. In some embodiments, the laser may output with a pulse energy of about 10 mJ to about 100 J, more particularly about 100 mJ to about 1 J. In some embodiments, the laser beam used for direct irradiation may have a smaller pulse period and/or pulse energy than that of the laser beam used for generating laser-induced shock wave such as those illustrated in FIGS. 1-3. The direct laser beam 504 may be defocused by optical diffusers to cover a larger area of the die 502 surface than the laser itself, such as 10 mm² to 10 cm², depending upon the power of the laser, and may clean an entire die at once in some embodiments. In some embodiments, the laser beam may be shaped into a line or a thin rectangular shape. In some embodiments, the laser beam may be scanned across a die or a wafer. In one embodiment, the diffused beam 504 can cover 1 cm² ±10%. Whether or not diffused, the laser assembly 510 and/or the die-supporting robotics may be programmed to scan the laser beam 504 across the entire die 502 surface to be bonded, to the extent the (possibly diffused) beam 504 is not large enough to reach the entire die 502. Some of the walls of the chamber 512 may be opaque or may include optical filters to block the laser wavelength for safety measures, which is also true of the laser cleaning chamber walls of other embodiments described herein. Then, the cleaned die 502 may be moved to a location for bonding (for example, direct bonding, such as the ZIBOND® and DBI® and DBI® Ultra processes) with another element 505 (e.g., a wafer or a die) being held by a support. As with the laterally oriented embodiments described above, the example apparatus and sequence illustrated in FIG. 5 may be used to effectively remove particles from the bonding surface, and may additionally clean organic residue.

In both dry laser cleaning and steam laser cleaning, contaminants can be removed from solid surfaces by laser irradiation directly onto the surfaces. In some embodiments, the laser beam may be directed substantially perpendicularly to the surfaces. In dry laser cleaning, contaminants are removed from solid surfaces by laser-induced fast thermal expansion of contaminants and/or solid surfaces or laser ablation of contaminants. In steam laser cleaning, the beam can be directed orthogonally or parallel to the substrate surface, and contaminants are removed by laser-induced explosive vaporization of the fluid coating on the solid surfaces. See “Laser-cleaning techniques for removal of surface particles. (pp. 3515-3523) J. Appl. Phys. 71(7), 1992 by A. C. Tam, W. P. Leung, W. Zapka and W. Ziemlich”, the disclosure of which is incorporated herein by reference in its entirety for all purposes, for further details regarding dry laser cleaning and steam laser cleaning.

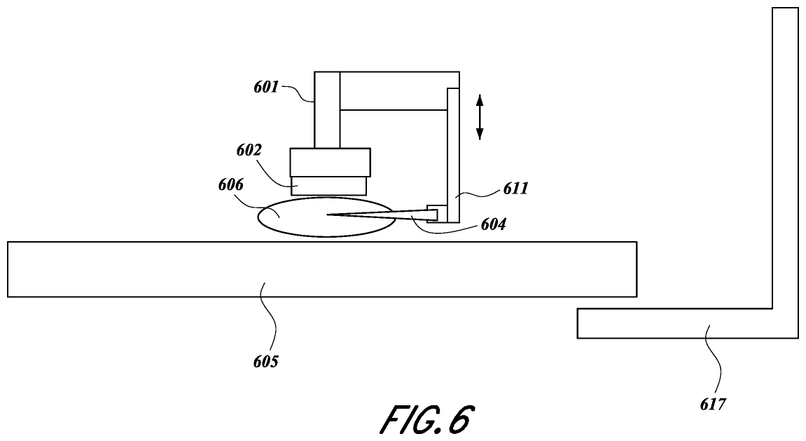

FIG. 6 illustrates an example of a cleaning and bonding system which can clean two elements 602 and 605, e.g., a die and a wafer (or a substrate or a carrier), or two dies, to be bonded to one another. The system may include safety walls 617 having non-transparent material or optical filter that can block the laser wavelength but may be transparent in other wavelengths. The system may include a support configured to hold a first element 605 (e.g., a wafer or a die) during bonding (for example, direct bonding, such as the ZIBOND® and DBI® and DBI® Ultra processes). The system may further include robotic die handler 601 (e.g., a flip tool) configured to pick up a second element 602 (e.g., a die) from a tape or carrier and to deliver the second element 602 to a bonding tool where the bonding occurs. The system may further include a laser 611 configured to perform the cleaning process illustrated in FIG. 1. In some embodiments, the cleaning process may involve steam laser cleaning. The illustrated laser source 611 generates a focused laser beam 604 that induces a plasma 606 from ambient or supplied fluid. The laser 611 and any optical elements (e.g., focusing elements) may be integrated with the robotic die handler 601. The relative positions of the laser 611, the flip tool 601, and the support may be mechanically adjusted such that the laser beam 604 can be focused either near the first element 605 or the second element 602. Therefore, both the first element 605 and the second element 602 can be cleaned, simultaneously (if the elements 602, 605 are close enough to one another) or in sequence (using the vertical adjustment).

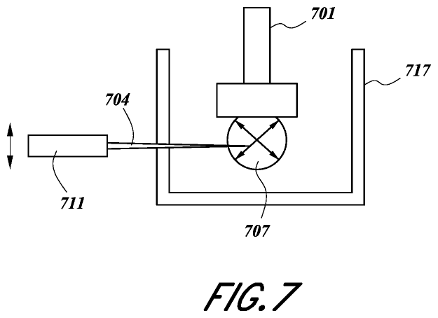

FIG. 7 illustrates an example use of the disclosed systems and methods to clean the flip tool 701 with the cleaning process illustrated in FIG. 1. In some embodiments, the cleaning process may involve steam laser cleaning. The relative positions of the laser 711 and the flip tool 701 may be mechanically adjusted such that the laser beam can be focused near an end effector surface of the flip tool 701. As in the previously described embodiments, the laser cleaning chamber walls 717 may be opaque to or filter the laser wavelengths and other dangerous wavelengths that may be generated by its use (e.g., emitted by a laser-induced plasma), but may have a window to permit entry of the laser beam 704. As will be appreciated by the skilled artisan, use of the cleaning laser 711 (whether the illustrated laser-induced plasma shock wave 707 or the direct irradiation embodiment of FIG. 5) in the absence of a die can be employed to clean the handling surface of a robotic die handler 701 (e.g., the flip tool). Similarly, it will be appreciated that, in the absence of the first and/or second elements, the laser cleaning of FIG. 6 can clean robotic die handlers, such as the flip tool and/or the substrate support of the bonding tool. The relative positions of the laser 711, the flip tool 701, and the substrate support of the bonding tool may be mechanically adjusted such that the laser beam 704 can be focused either near the flip tool or the substrate support of the bonding tool.

In certain embodiments, the chamber described herein comprises walls for protection against harmful laser light affecting workers and/or for containment/redirection of fluids or particles dislodged from die surfaces. Chamber walls can have windows for viewing or allowing laser light to pass into the chamber. The chamber walls can be opaque to the energetic laser light of interest and/or other dangerous wavelengths (e.g., UV light emitted by a laser-induced plasma) in order to protect against harm to workers or surrounding equipment, or can be arranged to filter the laser light and allow other visible wavelengths to pass to allow visual inspection. Opaque walls with filter inspection windows may also be employed. In some cases, safety wall(s) can be positioned to protect against escape of laser light. The safety wall(s) may or may not enclose a chamber. In other cases, walls can be arranged to additionally enclose a region for the cleaning operation and facilitate directed evacuation to pull particles away from the bonding surface and pick-and-place robotic equipment.

Embodiments described herein employ a laser to provide energy to a bonding surface that can dislodge particles and/or volatilize contaminating residue from the bonding surface in a dry process or a process utilizing steams or droplets or other fluids. An example laser for such purposes is a neodymium-doped yttrium aluminum garnet (Nd:YAG) laser with an output wavelength of about 1064 nm. Other example lasers for such purposes include diode lasers emitting light in the blue or green color range. However, the skilled artisan will appreciate that other types of lasers can serve the desired function of imparting energy to clean the bonding surface, directly or by way of a laser-induced plasma shock wave. In some embodiments, the output wavelength of a laser may be between about 100 nm to about 1500 nm, or more particularly between about 400 nm to about 1200 nm.

In some embodiments, software written to perform the methods as described herein, including robotic movements for the die handler and/or the laser in the sequences described herein, is stored in some form of computer readable medium, such as memory, CD-ROM, DVD-ROM, memory stick, flash drive, hard drive, SSD hard drive, server, mainframe storage system and the like.

### Electronic Elements

Embodiments described herein include directly bonding a second element to a first electronic element that is mounted to the support of a bonding tool and can be referred to as the host element in the direct bonding process, such as hybrid bonding. The first element can be a substrate comprising multiple devices, such as a processed wafer, to be separated at a different time. The first element can also be a wafer or a die, but is illustrated as a semiconductor wafer herein. The first element can also be a ceramic or glass substrate in some examples. Either of the elements can comprise an electronic element (e.g., passive component), a semiconductor element (e.g., an integrated circuit die) or an optical element (e.g., a lens, filter, grating, emitter or sensor device). Both elements can include bonding layers configured for direct bonding as described herein.

A die can refer to any suitable type of integrated device die. For example, the integrated device dies can comprise an electronic component such as an integrated circuit (such as a processor die, a controller die, or a memory die), a microelectromechanical systems (MEMS) die, an optical device, or any other suitable type of device die. In some embodiments, the electronic component can comprise a passive device such as a capacitor, inductor, or other surface-mounted device. Circuitry (such as active components like transistors) can be patterned at or near active surface(s) of the die in various embodiments. The active surface may be on a side of the die which is opposite the backside of the die. The backside may or may not include any active circuitry or passive devices.

An integrated device die can comprise a bonding surface and a back surface opposite the bonding surface. The bonding surface can have a plurality of conductive bond pads including a conductive bond pad, and a non-conductive material proximate to the conductive bond pad. In some embodiments, the conductive bond pads of the integrated device die can be directly bonded to the corresponding conductive pads of the substrate or wafer without an intervening adhesive, and the non-conductive material of the integrated device die can be directly bonded to a portion of the corresponding non-conductive material of the substrate or wafer without an intervening adhesive. Directly bonding without an adhesive is described throughout U.S. Pat. Nos. 7,126,212; 8,153,505; 7,622,324; 7,602,070; 8,163,373; 8,389,378; 7,485,968; 8,735,219; 9,385,024; 9,391,143; 9,431,368; 9,953,941; 9,716,033; 9,852,988; 10,032,068; 10,204,893; 10,434,749; and 10,446,532, the contents of each of which are hereby incorporated by reference herein in their entirety and for all purposes.

### Examples of Direct Bonding Methods and Directly Bonded Structures

Various embodiments disclosed herein relate to directly bonded structures in which two elements can be directly bonded to one another without an intervening adhesive. Two or more electronic elements, which can be semiconductor elements (such as integrated device dies, wafers, etc.), may be stacked on or bonded to one another to form a bonded structure. Conductive contact pads of one element may be electrically connected to corresponding conductive contact pads of another element. Any suitable number of elements can be stacked in the bonded structure. The contact pads may comprise metallic pads formed in a nonconductive bonding region, and may be connected to underlying metallization, such as a redistribution layer (RDL).

In some embodiments, the elements are directly bonded to one another without an adhesive. In various embodiments, a non-conductive or dielectric material of a first element can be directly bonded to a corresponding non-conductive or dielectric field region of a second element without an adhesive. The non-conductive material can be referred to as a nonconductive bonding region or bonding layer of the first element. In some embodiments, the non-conductive material of the first element can be directly bonded to the corresponding non-conductive material of the second element using dielectric-to-dielectric bonding techniques. For example, dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. Suitable dielectric materials for direct bonding include but are not limited to inorganic dielectrics, such as silicon oxide, silicon nitride, or silicon oxynitride, or can include carbon, such as silicon carbide, silicon oxycarbonitride, silicon carbonitride or diamond-like carbon. In some embodiments, the dielectric materials do not comprise polymer materials, such as epoxy, resin or molding materials.

In various embodiments, hybrid direct bonds can be formed without an intervening adhesive. For example, dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two dielectric materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a hybrid bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The nonconductive bonding regions can be directly bonded to one another without an adhesive at room temperature in some embodiments in the bonding tool described herein and, subsequently, the bonded structure can be annealed. Annealing can be performed in a separate apparatus. Upon annealing, the contact pads can expand and contact one another to form a metal-to-metal direct bond. Beneficially, the use of hybrid bonding techniques, such as Direct Bond Interconnect, or DBI®, available commercially from Xperi of San Jose, Calif., can enable high density of pads connected across the direct bond interface (e.g., small or fine pitches for regular arrays). In some embodiments, the pitch of the bonding pads, or conductive traces embedded in the bonding surface of one of the bonded elements, may be less 40 microns or less than 10 microns or even less than 2 microns. For some applications the ratio of the pitch of the bonding pads to one of the dimensions of the bonding pad is less than 5, or less than 3 and sometimes desirably less than 2. In other applications the width of the conductive traces embedded in the bonding surface of one of the bonded elements may range between 0.3 to 3 microns. In various embodiments, the contact pads and/or traces can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. In embodiments described herein, whether a die or a substrate, the first element can be considered a host substrate and is mounted on a support in the bonding tool to receive the second element from a pick-and-place or robotic end effector. The second element of the illustrated embodiments comprises a die. In other arrangements, the second element can comprise a carrier or substrate (e.g., a wafer).

As explained herein, the first and second elements can be directly bonded to one another without an adhesive, which is different from a deposition process. In one application, a width of the first element in the bonded structure can be similar to a width of the second element. In some other embodiments, a width of the first element in the bonded structure can be different from a width of the second element. The width or area of the larger element in the bonded structure may be at least 10% larger than the width or area of the smaller element. The first and second elements can accordingly comprise non-deposited elements. Further, directly bonded structures, unlike deposited layers, can include a defect region along the bond interface in which nanovoids are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. In embodiments that utilize an oxygen plasma for activation, an oxygen peak can be formed at the bond interface. In some embodiments, the bond interface can comprise silicon oxynitride, silicon oxycarbonitride, or silicon carbonitride. As explained herein, the direct bond can comprise a covalent bond, which is stronger than van der Waals bonds. The bonding layers can also comprise polished surfaces that are planarized to a high degree of smoothness.

In various embodiments, the metal-to-metal bonds between the contact pads can be joined such that copper grains grow into each other across the bond interface. In some embodiments, the copper can have grains oriented along the 111 crystal plane for improved copper diffusion across the bond interface. The bond interface can extend substantially entirely to at least a portion of the bonded contact pads, such that there is substantially no gap between the nonconductive bonding regions at or near the bonded contact pads. In some embodiments, a barrier layer may be provided under the contact pads (e.g., which may include copper). In other embodiments, however, there may be no barrier layer under the contact pads, for example, as described in US 2019/0096741, which is incorporated by reference herein in its entirety and for all purposes.

In one aspect, a system for direct bonding is disclosed. The system can include a bonding tool including a support configured to hold a first element. The bonding tool is configured to bond a second element to the first element by way of direct bonding. The system can also include a laser cleaning assembly configured to clean the first element and/or the second element.

In one embodiment, the laser cleaning assembly is configured to clean the second element.

In one embodiment, the laser cleaning assembly is configured to clean a surface of the first element and/or the second element by generating a laser beam substantially parallel to the surface.

In one embodiment, the laser cleaning assembly is further configured to clean the bonding tool and/or a robotic end effector configured to deliver the second element to the bonding tool.

In one embodiment, the first element is a semiconductor element.

In one embodiment, the second element is a semiconductor element.

In one embodiment, the second element is an electronic element.

In one embodiment, the second element is an optical element.

In one embodiment, the laser cleaning assembly comprises a beam irradiator configured to generate a laser beam and to focus the laser beam onto a focal point to generate a plasma shock wave around the focal point.

In one embodiment, the plasma shock wave removes contaminants on a surface of the second element and/or the first element.

In one embodiment, the beam irradiator comprises at least one laser configured to generate the laser beam.

In one embodiment, the at least one laser comprises a Nd:YAG laser.

In one embodiment, an output wavelength of light of the at least one laser is between about 100 nm to about 1500 nm.

In one embodiment, the laser beam has a pulse frequency of about 0.5 to about 50 pulses per second and/or a pulse period of about 0.01 nanosecond to about 100 nanoseconds and/or a pulse energy of about 0.01 J to about 100 J.

In one embodiment, the laser beam lasts for between about 0.01 second and 10 seconds.

In one embodiment, the beam irradiator comprises one or more reflectors and/or refractors configured to control a path of the laser beam.

In one embodiment, the beam irradiator comprises a focusing lens configured to focus the laser beam onto the focal point.

In one embodiment, the laser cleaning assembly comprises a chamber configured to receive a fluid (e.g., gases, steams, sprays or liquid droplets), wherein the plasma shock wave is generated by focusing the laser beam onto the focal point within the fluid.

In one embodiment, the chamber comprises a window configured to transmit the laser beam.

In one embodiment, at least one of the walls of the chamber comprises a filter for blocking the laser beam.

In one embodiment, at least one of the walls of the chamber is opaque at least with respect to the laser beam.

In one embodiment, the system further includes a fluidic apparatus configured to supply the fluid to the chamber.

In one embodiment, the fluidic apparatus comprises a droplet dispenser.

In one embodiment, the fluid comprises droplets and/or liquid jets.

In one embodiment, the fluid comprises liquid chemical, water, ozonated water, hydrogenated water and/or deionized water.

In one embodiment, the fluid comprises an ionized gas.

In one embodiment, the fluid comprises Ar, He, Ne, N₂ and/or a chemically reactive gaseous species.

In one embodiment, the laser cleaning assembly is configured to clean the second element and/or the first element by way of direct irradiation.

In one embodiment, the laser cleaning assembly is further configured to generate a laser beam normal to a surface to be cleaned.

In one embodiment, the laser cleaning assembly comprises one or more reflectors and/or refractors and/or focusing lens configured to control a path and/or a focus of the laser beam.

In one embodiment, the laser cleaning assembly is configured to scan the laser beam across the surface.

In one embodiment, the laser cleaning assembly further comprises optical diffusers configured to spread light evenly across a surface to be cleaned.

In one embodiment, the laser cleaning assembly comprises a chamber where cleaning of the second element occurs, and wherein at least one of the walls of the chamber comprises a filter for blocking the laser beam.

In one embodiment, the laser cleaning assembly comprises a chamber where cleaning of the second element occurs, and wherein at least one of the walls of the chamber is opaque at least with respect to the laser beam.

In one embodiment, the laser cleaning assembly is configured to clean the second element and/or the first element and/or the support by way of dry laser cleaning and/or steam laser cleaning and/or laser shock cleaning.

In one embodiment, the system further includes a processor configured to activate the laser cleaning assembly prior to the direct bonding.

In one embodiment, the processor is further configured to activate the laser cleaning assembly before or after the direct bonding for cleaning the support and/or a robotic end effector for the second element.

In one embodiment, the processor is further configured to detect completion of laser cleaning of the second element; and in response to detection of completion of laser cleaning, automatically deliver the second element to the support.

In one embodiment, the processor is further configured to actuate an output power of the at least one laser.

In one embodiment, the processor is further configured to control the pulse period and/or the pulse energy of the laser beam.

In one embodiment, the system further includes a processor configured to control position and/or orientations of the reflectors and/or refractors.

In one embodiment, the system further includes a processor configured to control a position of the focal point and/or a position of the focusing lens.

In one embodiment, the processor is further configured to control a rate at which the fluid is received by the chamber, and/or select a composition of the fluid being supplied by the fluidic apparatus to the chamber.

In one embodiment, the system further includes a user interface configured to receive information from a user.

In one embodiment, the processor is further configured to, based on the received information, actuate an output power of the at least one laser.

In one embodiment, the processor is further configured to, based on the received information, control the pulse period and/or the pulse energy of the laser beam.

In one embodiment, the processor is further configured to, based on the received information, control position and/or orientations of the reflectors and/or refractors.

In one embodiment, the processor is further configured to, based on the received information, control a position of the focal point and/or a position of the focusing lens.

In one embodiment, the processor is further configured to, based on the received information, control a rate at which the fluid is received by the chamber.

In one embodiment, the processor is further configured to, based on the received information, select a composition of the fluid being supplied by the fluidic apparatus to the chamber.

In one embodiment, the system further includes a vacuum evacuator configured to remove contaminants from the chamber.

In one embodiment, the first element is a wafer and the second element is a die.

In one aspect, a method of direct bonding is disclosed. The method can include holding a first element with a support in a bonding tool. The method can also include cleaning the first element and/or a second element using a laser cleaning assembly. The method can also include directly bonding the second element to the first element, without an intervening adhesive, using the bonding tool, while holding the first element and after cleaning the second element.

In one embodiment, the second element is cleaned by the laser cleaning assembly.

In one embodiment, the method further includes cleaning a robotic end effector configured to deliver the second element to the bonding tool using the laser cleaning assembly.

In one embodiment, the method further includes cleaning the support in the bonding tool using the laser cleaning assembly.

In one embodiment, the cleaning comprises generating a laser beam and focusing the laser beam onto a focal point, using at least one lens.

In one embodiment, the cleaning comprises generating a plasma shock wave around the focal point.

In one embodiment, the laser beam is parallel to a surface of the second element to be cleaned.

In one embodiment, the plasma shock wave removes contaminants on a surface of the second element and/or the first element.

In one embodiment, generating the laser beam using at least one lens comprises generating a local plasma from ambient fluid.

In one embodiment, generating the laser beam comprises employing a Nd:YAG laser.

In one embodiment, an output wavelength of light of the at least one laser is between about 100 nm to about 1500 nm.

In one embodiment, the laser beam has a pulse frequency of about 0.5 to about 50 pulses per second and/or a pulse period of about 0.01 nanosecond to about 100 nanoseconds and/or a pulse energy of about 0.01 J to about 100 J.

In one embodiment, the laser beam lasts for between about 0.01 second and 10 seconds.

In one embodiment, the method further includes controlling a path of the laser beam using one or more reflectors and/or refractors.

In one embodiment, the method further includes focusing the laser beam onto the focal point using multiple optical elements.

In one embodiment, the method further includes receiving a fluid in a chamber of the laser cleaning assembly, wherein the plasma shock wave is generated by focusing the laser beam onto the focal point within the fluid.

In one embodiment, the chamber comprises a window configured to transmit the laser beam.

In one embodiment, at least one of the walls of the chamber comprises a filter for blocking the laser beam.

In one embodiment, at least one of the walls of the chamber is opaque at least with respect to the laser beam.

In one embodiment, the method further includes supplying the fluid to the chamber using a fluidic apparatus of the laser cleaning assembly.

In one embodiment, the fluidic apparatus comprises a droplet dispenser.

In one embodiment, the fluid comprises droplets and/or liquid jets.

In one embodiment, the fluid comprises liquid chemical, water, ozonated water, hydrogenated water and/or deionized water.

In one embodiment, the fluid comprises an ionized gas.

In one embodiment, the fluid comprises Ar, He, Ne, N₂ and/or a chemically reactive gaseous species.

In one embodiment, cleaning the first element and/or the second element is by way of direct irradiation.

In one embodiment, direct irradiation comprises generating a laser beam normal to a surface to be cleaned.

In one embodiment, a path and/or a focus of the laser beam is controlled by one or more reflectors and/or refractors and/or focusing lens.

In one embodiment, cleaning comprises scanning the laser beam across the surface to be cleaned.

In one embodiment, direct irradiation comprises spreading light evenly across a surface to be cleaned by optical diffusers.

In one embodiment, the method further includes cleaning the second element and/or the first element by way of dry laser cleaning and/or steam laser cleaning and/or laser shock cleaning.

In one embodiment, the method further includes, by a processor, activating the laser cleaning assembly for cleaning the first element and/or the second element prior to the bonding, or activating the laser cleaning assembly before or after the bonding for cleaning the support and/or a robotic end effector for carrying the second element.

In one embodiment, the method further includes, by a processor, detecting completion of laser cleaning of the second element; and in response to detection of completion of laser cleaning, automatically delivering the second element to the support of the bonding tool.

In one embodiment, the method further includes, by a processor, actuating an output power of the at least one laser.

In one embodiment, the method further includes, by a processor, controlling the pulse period and/or the pulse energy of the laser beam.

In one embodiment, the method further includes, by a processor, controlling position and/or orientations of the reflectors and/or refractors.

In one embodiment, the method further includes, by a processor, controlling a position of the focal point and/or a position of the focusing lens.

In one embodiment, the method further includes, by a processor, controlling a rate at which the fluid is received by the chamber, and/or selecting a composition of the fluid being supplied by the fluidic apparatus to the chamber.

In one embodiment, the method further includes receiving information from a user via a user interface.

In one embodiment, the method further includes, by a processor, actuating an output power of the at least one laser, based on the received information.

In one embodiment, the method further includes, by a processor, controlling the pulse period and/or the pulse energy of the laser beam, based on the received information.

In one embodiment, the method further includes, by a processor, controlling position and/or orientations of the reflectors and/or refractors, based on the received information.

In one embodiment, the method further includes, by a processor, controlling a position of the focal point and/or a position of the focusing lens, based on the received information.

In one embodiment, the method further includes, by a processor, controlling a rate at which the fluid is received by the chamber, based on the received information.

In one embodiment, the method further includes, by a processor, selecting a composition of the fluid being supplied by the fluidic apparatus to the chamber, based on the received information.

In one embodiment, the method further includes removing contaminants by a vacuum evacuator.

In one embodiment, the first element is a wafer and the second element is a die.

In one embodiment, directly bonding comprises directly bonding conductive materials and non-conductive materials.

In one embodiment, the first element is a semiconductor element.

In one embodiment, the second element is a semiconductor element.

In one embodiment, the second element is an electronic element.

In one embodiment, the second element is an optical element.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method of direct bonding, comprising:
holding a first element with a support in a bonding tool;
cleaning the first element and/or a second element using a laser cleaning assembly; and
directly bonding the second element to the first element, without an intervening adhesive, using the bonding tool, while holding the first element and after cleaning the first element and/or the second element.

2. The method of claim 1, wherein the second element is cleaned by the laser cleaning assembly.

3. The method of claim 1, further comprising cleaning a robotic end effector configured to deliver the second element to the bonding tool using the laser cleaning assembly.

4. The method of claim 1, further comprising cleaning the support in the bonding tool using the laser cleaning assembly.

5. The method of claim 1, wherein the cleaning comprises generating a laser beam and focusing the laser beam onto a focal point, using at least one lens.

6. The method of claim 5, further comprising, by a processor, actuating an output power of at least one laser and/or controlling the pulse period and/or the pulse energy of the laser beam.

7. The method of claim 5, wherein the cleaning comprises generating a plasma shock wave around the focal point, and the laser beam comprises a component parallel to a surface of the second element to be cleaned.

8. The method of claim 7, further comprising receiving a fluid in a chamber of the laser cleaning assembly, wherein the plasma shock wave is generated by focusing the laser beam onto the focal point within the fluid.

9. The method of claim 1, wherein cleaning the first element and/or the second element is by way of direct irradiation.

10. The method of claim 9, wherein direct irradiation comprises generating a laser beam normal to a surface to be cleaned.

11. The method of claim 10, wherein cleaning comprises scanning the laser beam across the surface to be cleaned.

12. The method of claim 1, wherein cleaning the first element and/or the second element comprises dry laser cleaning and/or steam laser cleaning and/or laser shock cleaning.

13. The method of claim 1, further comprising, by a processor:
activating the laser cleaning assembly for cleaning the first element and/or the second element prior to the bonding, or
activating the laser cleaning assembly before or after the bonding for cleaning the support and/or a robotic end effector for carrying the second element.

14. The method of claim 1, further comprising, by a processor:
detecting completion of laser cleaning of the second element; and
in response to detection of completion of laser cleaning, automatically delivering the second element to the support of the bonding tool.

15. The method of claim 1, further comprising removing contaminants by a vacuum evacuator.

16. The method of claim 1, wherein directly bonding the second element to the first element comprises directly bonding a conductive material of the first element to a conductive material of the second element and directly bonding a non-conductive material of the first element to a non-conductive material of the second element.

17. The method of claim 1, wherein the first element is a semiconductor element and the second element is a semiconductor element, an electronic element or an optical element.

18. A system for direct bonding, comprising:
a bonding tool to bond a first element to a second element using direct bonding, the bonding tool including a support to hold a first element; and
a laser cleaning assembly to clean the first element and/or the second element.

19. The system of claim 18, wherein the laser cleaning assembly comprises a beam irradiator to generate a laser beam and to focus the laser beam onto a focal point to generate a plasma shock wave around the focal point.

20. A bonding tool for hybrid bonding, comprising:
a support to hold a first element; and
a robotic end effector to hold a second element and hybrid direct bond the second element to the first element on the support;
a laser cleaning assembly to clean the first element on the support and/or the second element held by the robotic end effector.
